(19) United States
(12) Patent Application Publication
(10) Pub. No.: US 2019/0198697 A1
(43) Pub. Date: Jun. 27, 2019

(54) SOLAR CELL, MULTIJUNCTION SOLAR CELL, SOLAR CELL MODULE AND SOLAR POWER GENERATION SYSTEM

(71) Applicant: KABUSHIKI KAISHA TOSHIBA, Tokyo (JP)

(72) Inventors: Yuya Honishi, Yokohama Kanagawa (JP); Soichiro Shibasaki, Nerima Tokyo (JP); Mutsuki Yamazaki, Yokohama Kanagawa (JP); Sara Yoshio, Yokohama Kanagawa (JP); Naoyuki Nakagawa, Setagaya Tokyo (JP); Kazushige Yamamoto, Yokohama Kanagawa (JP)

(21) Appl. No.: 16/289,711

(22) Filed: Mar. 1, 2019

Related U.S. Application Data
(63) Continuation of application No. PCT/JP2018/010654, filed on Mar. 16, 2018.

(30) Foreign Application Priority Data
Sep. 19, 2017 (JP) 2017-179482

(51) Int. Cl. H01L 31/0725; H01L 31/0336; H01L 31/0224; H01L 31/0236

(52) U.S. Cl. CPC H01L 31/0725; H01L 31/02363; H01L 31/022425; H01L 31/0336

(57) ABSTRACT

A solar cell of an embodiment includes a first electrode, a light absorption layer, an n-type layer, and a second electrode. The light absorption layer exists between the first electrode and the n-type layer. The n-type layer exists between the light absorption layer and the second electrode. The light absorption layer contains Cu₂O. The n-type layer contains a sulfide.

### CROSS-REFERENCE TO RELATED APPLICATIONS

This application is a Continuation application of International Application PCT/JP2018/010654, the International Filing Date of which is Mar. 16, 2018, and claims the benefit of priority from Japanese patent application No. 2017-179482, filed on Sep. 19, 2017, the entire contents of both of which are incorporated herein by reference.

### FIELD

Embodiments described herein relate to a solar cell, a multijunction solar cell, a solar cell module and a solar power generation system.

### BACKGROUND

There are multijunction (tandem) solar cells as highly efficient solar cells. In the tandem solar cell, a cell with high spectral sensitivity for each wavelength band can be used, and hence the tandem solar cell can be made more efficient than a single junction. Further, a Cu₂O compound has been expected as a top cell of the tandem solar cell, the compound being an inexpensive material and having a wide band gap. However, CuO is generated on the surface of the Cu₂O compound which is easily oxidized, to cause deterioration in characteristics of the pn interface and thus prevent the Cu₂O solar cell from having a conversion efficiency of not lower than 10%.

### BRIEF DESCRIPTION OF THE DRAWINGS

FIG. 1 is a is a sectional conceptual diagram of a solar cell according to an embodiment.

FIG. 2 is a sectional conceptual diagram of a multijunction solar cell according to an embodiment.

FIG. 3 is a conceptual diagram of a solar cell module according to an embodiment.

FIG. 4 is a sectional conceptual diagram of the solar cell module according to an embodiment.

FIG. 5 is a conceptual diagram of a solar cell system according to an embodiment.

### DETAILED DESCRIPTION

### First Embodiment

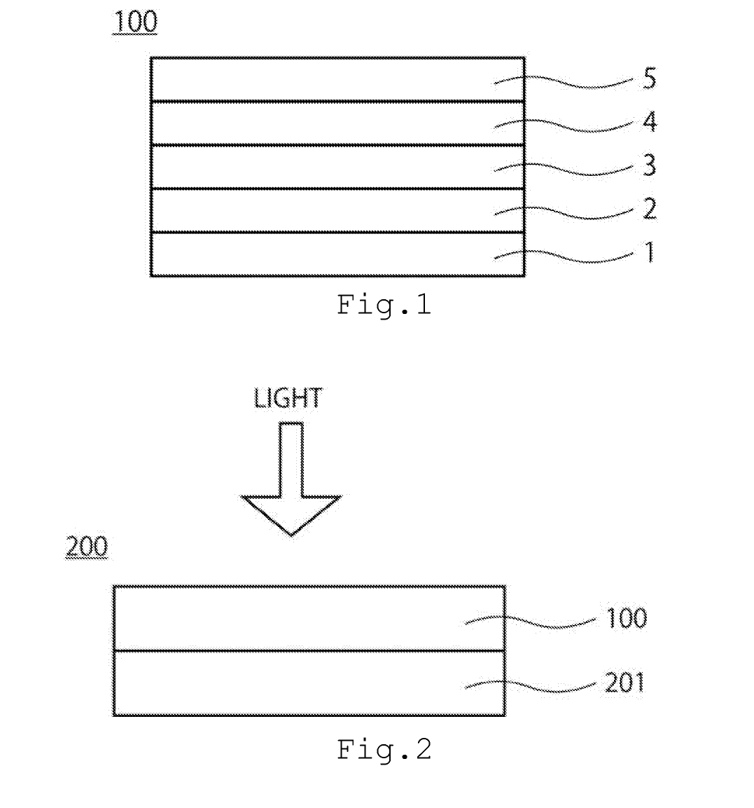

A first embodiment relates to a solar cell. FIG. 1 shows a conceptual diagram of a solar cell 100 of the first embodiment. As shown in FIG. 1, the solar cell 100 according to the present embodiment includes a substrate 1, a first electrode 2 on the substrate 1, a light absorption layer 3 on the first electrode 2, an n-type layer 4 on the light absorption layer 3, and a second electrode 5 on the n-type layer 4. An intermediate layer, not shown, may be included between the first electrode 2 and the light absorption layer 3 or between the n-type layer 4 and the second electrode 5.

(Substrate)

As the substrate 1 of the embodiment, soda-lime glass is preferably used, and there can also be used glass in general, such as quartz, white sheet glass or chemically strengthened glass, a metal plate such as stainless steel, Ti (titanium) or Cr (chromium), or a resin such as polyimide or acryl.

(First Electrode)

The first electrode 2 of the embodiment is a layer existing between the substrate 1 and the light absorption layer 3. In FIG. 1, the first electrode 2 is in direct contact with the substrate 1 and the light absorption layer 3. As the first electrode 2, a transparent conductive film, a metal film, or a laminate of the metal film and the transparent conductive film is preferred. The transparent conductive film is not particularly limited, and is a film of indium tin oxide (ITO), aluminum-doped zinc oxide (AZO), boron-doped zinc oxide (BZO), gallium doped zinc oxide (GZO), fluorine-doped tin oxide (FTO), antimony-doped tin oxide (ATO), titanium-doped Indium oxide (ITiO), indium zinc oxide (IZO), indium gallium zinc oxide (IGZO), or the like. The transparent conductive film may be a laminated film, and a film of tin oxide or the like besides the above oxides may be included in the laminated film. The metal film is not particularly limited and is a film of Mo, Au, W, or the like. The first electrode 2 may be an electrode formed by providing a metal in the form of dots, lines, or meshes on the transparent conductive film. At this time, the metal in the form of dots, lines, or meshes is disposed between the transparent conductive film and the light absorption layer 3. It is preferable for the metal in the form of dots, lines, or meshes to have an aperture ratio of not lower than 50% with respect to the transparent conductive film. The metal in the form of dots, lines, or meshes is not particularly limited and is Mo, Au, W, or the like.

(Light Absorption Layer)

The light absorption layer 3 of the embodiment is a layer existing between the first electrode 2 and the n-type layer 4. In FIG. 1, the light absorption layer 3 is in direct contact with the first electrode 2 and the n-type layer 4. The light absorption layer 3 is a p-type layer containing Cu₂O. Cu₂O is undoped or doped cuprous oxide. The thickness of Cu₂O is typically not smaller than 500 nm and not larger than 2000 nm, but is not limited thereto. Cu₂O is inexpensive compared with a compound having a chalcopyrite structure, thereby enabling reduction in cost of the solar cell 100. In addition, Cu₂O has a band gap of about 2.0 eV, which is a wide band gap. When the light absorption layer 3 of the solar cell 100 of the embodiment has a wide band gap, at the time of multijunction using as a bottom cell a solar cell that includes a light absorption layer having a narrow band gap, such as Si, the solar cell 100 of the embodiment is preferred in that the permeability of the wavelength contributing to power generation on the bottom cell side is high and the power generation amount on the bottom cell side is thus high. When the solar cell 100 of the embodiment is used as the multijunction solar cell, the solar cell 100 of the embodiment is preferably provided on the light incident side.

(n-Type Layer)

The n-type layer 4 of the embodiment is a layer existing between the light absorption layer 3 and the second electrode 5. In FIG. 1, the n-type layer 4 is in direct contact with the light absorption layer 3 and the second electrode 5. Although the light absorption layer containing Cu₂O has formed a pn junction together with an oxide-system n-type layer, in the embodiment, a layer containing a sulfide layer is preferred as the n-type layer 4 from the viewpoint of suppressing oxidation of the light absorption layer 3. In addition, the n-type layer 4 is more preferably a sulfide layer from the viewpoint of suppressing oxidation of the light absorption layer 3. The sulfide of the n-type layer 4 is preferably a sulfide compound containing Zn and In, a sulfide compound containing Cd and Zn, or a sulfide compound containing In and Ga. More specifically, the n-type layer 4 is preferably a layer containing at least one sulfide selected from the group consisting of ZnₓIn₂₋₂ₓS₃₋₂ₓ, Cd_{y}Zn_{1-y}S, and In_{z}Ga_{1-z}S. The n-type layer 4 is more preferably a layer made of one or more sulfides selected from the group consisting of ZnₓIn₂₋₂ₓS₃₋₂ₓ, Cd_{y}Zn_{1-y}S, and In_{z}Ga_{1-z}S. The n-type layer 4 is preferably a layer made of one type of sulfide selected from the group consisting of ZnₓIn₂₋₂ₓS₃₋₂ₓ, Cd_{y}Zn_{1-y}S and In_{2z}Ga_{21-2z}S. Using a sulfide rather than an oxide as the n-type layer 4 can suppress the oxidation of the light absorption layer 3 containing Cu₂O as compared with the case of using an oxide. Cu₂O is easily oxidized to CuO. When Cu₂O is oxidized, the pn interface becomes rough and the resistance of the interface increases, thus causing a decrease in conversion efficiency. In particular, the light absorption layer 3 containing Cu₂O placed under high temperature and high humidity conditions for a long time is easily oxidized when the n-type layer 4 is an oxide, but using a sulfide for the n-type layer 4 can suppress the oxidation of the absorption layer 3. With the state at the pn interface having a great influence on the conversion efficiency of the solar cell 100, it is preferable to use the n-type layer 4 of the embodiment in combination with the light absorption layer 3 containing Cu₂O.

The thickness of the n-type layer 4 is preferably not smaller than 5 nm and not larger than 100 nm. If the thickness of the n-type layer 4 is not larger than 5 nm, a leakage current occurs when coverage of the n-type layer 4 is poor, which is not preferred. If the thickness of the n-type layer 4 exceeds 100 nm, the transmittance decreases and a short-circuit current decreases, which is not preferred. Therefore, the thickness of the n-type layer 4 is more preferably not smaller than 10 nm and not larger than 50 nm. In order to achieve a film with good coverage, the surface roughness of the n-type layer is preferably not larger than 5 nm.

A conduction band offset (ΔE=E_{cp}−E_{cn}), being a difference between a position (E_{cp} (eV)) of the conduction band minimum (CBM) of the light absorption layer 3 and a position (E_{cn} (eV)) below the conductive band of the n-type layer 4 is not smaller than −0.2 eV and not larger than 0.6 eV (−0.2 eV≤ΔE≤+0.6 eV). When the conduction band offset is larger than 0, the conduction band at the pn junction interface becomes discontinuous and spikes occur. When the conduction band offset is smaller than 0, the conduction band at the pn junction interface becomes discontinuous and cliffs occur. Both spikes and cliffs are barriers to photogenerated electrons, so smaller ones are preferred. Hence the conduction band offset is preferably not smaller than 0.0 eV and not larger than 0.4 eV (0.0 eV≤ΔE≤+0.4 eV). The position of CBM can be estimated using the following method. The valence band maximum (VBM) is actually measured by photoemission spectroscopy, which is an evaluation method of the electron occupancy level, and CBM is then calculated assuming a known band gap. However, at the actual pn junction interface, an ideal interface such as mutual diffusion and cation vacancy generation is not maintained, and hence the band gap is likely to change. Therefore, CBM is also preferably evaluated by inverse photoemission spectroscopy which directly uses the inverse process of photoelectron emission. Specifically, the electronic state of the pn junction interface can be evaluated by repeating low energy ion etching and positive/inverse photoemission spectroscopy on the surface of the photoelectric conversion element

x of ZnₓIn₂₋₂ₓS₃₋₂ₓ satisfies 0≤x≤1. ZnS is not preferred because it has a large conduction band offset with Cu₂O. Preferable x satisfies 0.0≤x≤0.6, and more preferable x satisfies 0.0≤x≤0.3. Within this range, the barrier of photogenerated electrons is small, and the sulfide is preferred from the viewpoint of preventing deterioration in quality of the pn junction interface.

y of Cd_{y}Zn_{1-y}S satisfies 0<y≤1. ZnS is not preferred because it has a large conduction band offset with Cu₂O. Preferable y satisfies 0.3≤y≤0.7, and more preferable y is 0.4≤y≤0.6. Within this range, the barrier of photogenerated electrons is small, and the sulfide is preferred from the viewpoint of preventing deterioration in quality of the pn junction interface.

z of In_{2z}Ga_{21-2z}S₃ satisfies 0<z≤1. Ga₂S₃ is not preferred because having a large conduction band offset with Cu₂O. Preferable z satisfies 0.2≤z≤1.0, and more preferable z satisfies 0.5≤z≤1.0. Within this range, the barrier of photogenerated electrons is small, and the sulfide is preferred from the viewpoint of preventing deterioration in quality of the pn junction interface.

(Second Electrode)

In FIG. 1, the second electrode 5 is in direct contact with the n-type layer 4. As the second electrode 5, a transparent conductive film is preferred. The same material as that of the first electrode 2 is preferably used for the transparent conductive film.

The composition and the like of the solar cell 100 are obtained by X-ray photoemission spectroscopy (XPS) and secondary ion mass spectrometry (SIMS). In addition, the thickness and particle size of each layer may be obtained by measuring a cross section of the solar cell 100 with a transmission electron microscope (TEM) at 100,000 times. The surface roughness may be obtained by performing observation with an atomic force microscope (AFM).

### Second Embodiment

The second embodiment relates to a multijunction solar cell. FIG. 2 is a sectional conceptual diagram of a multijunction solar cell 200 of the second embodiment. The multijunction solar cell 200 of FIG. 2 includes the solar cell (first solar cell) 100 of the first embodiment and a second solar cell 201 on the light incident side. A light absorption layer of the second solar cell 201 has a smaller band gap than that of the light absorption layer 3 of the solar cell 100 of the first embodiment. Note that the multijunction solar cell of the embodiment also includes a solar cell in which three or more solar cells are bonded.

The light absorption layer 3 of the solar cell 100 of the first embodiment has a band gap of about 2.0 eV, and hence the light absorption layer of the second solar cell 201 is preferably has a band gap of not smaller than 1.0 eV and not larger than 1.4 eV. The light absorption layer of the second solar cell 201 is preferably at least one compound semiconductor layer or crystalline silicon or more of a CIGS type, a CIT type and a CdTe type having a high In content ratio.

### Third Embodiment

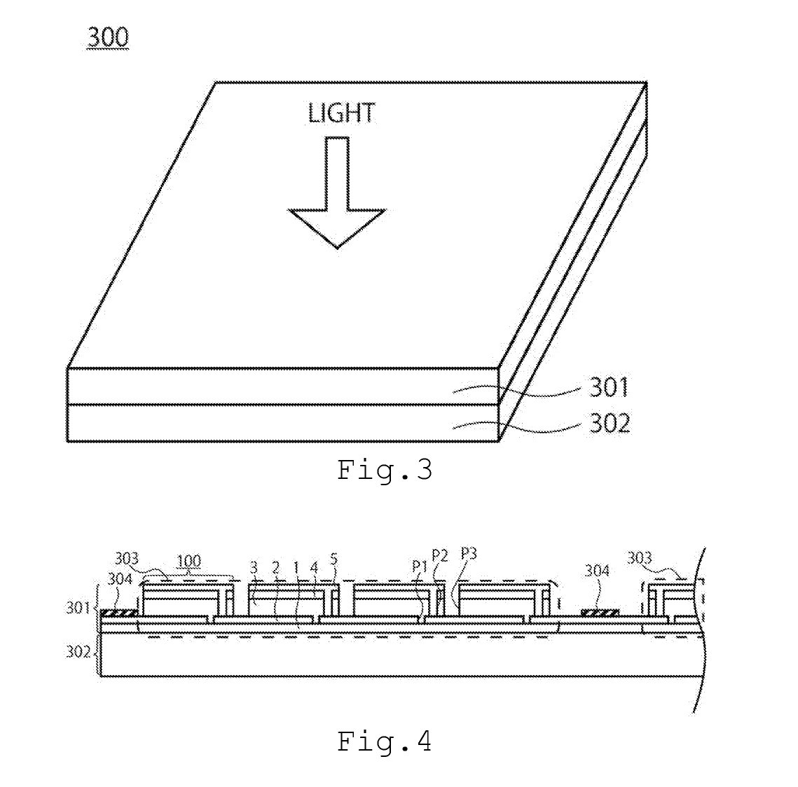

The third embodiment relates to a solar cell module. FIG. 3 is a perspective conceptual diagram of a solar cell module 300 of the third embodiment. The solar cell module 300 of FIG. 3 is a solar cell module in which the first solar cell module 301 and the second solar cell module 302 are laminated. The first solar cell module 301 is on the light incident side, and for the first solar cell module 301, the solar cell 100 of the first embodiment is used. For the second solar cell module 302, the second solar cell 201 is preferably used.

FIG. 4 is a sectional conceptual diagram of the solar cell module 300. In FIG. 4, the structure of the first solar cell module 301 is shown in detail, and the structure of the second solar cell module 302 is not shown. In the second solar cell module 301, the structure of the solar cell module is appropriately selected in accordance with a light absorption layer and the like of the solar cell to be used. The solar cell module of FIG. 4 includes a plurality of submodules 303 surrounded by broken lines in which a plurality of solar cells 100 (solar cells) are laterally arranged and electrically connected in series, and the plurality of submodules 303 are electrically connected in parallel or in series. The adjacent submodules 303 are electrically connected by a bus bar 304.

The solar cell 100 has been scribed, and in the adjacent solar cell 100, the second electrode 5 on the upper side, and the first electrode 2 on the lower side are connected. Similarly to the solar cell 100 of the first embodiment, the solar cell 100 of the third embodiment also has a substrate 1, a first electrode 2, a light absorption layer 3, an n-type layer 4, and a second electrode 5. It is preferable that both ends of the solar cell 100 in the submodule 303 be connected to the bus bar 304, and that the bus bar 304 electrically connect the plurality of submodules 303 in parallel or in series to adjust an output voltage with the second solar cell module 302.

### Fourth Embodiment

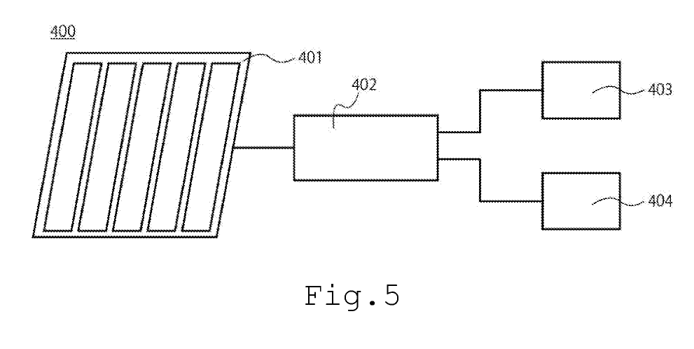

The fourth embodiment relates to a solar power generation system. The solar cell module 300 of the third embodiment can be used as a power generator for generating electricity in the solar power generation system of the fourth embodiment. The solar power generation system of the embodiment performs power generation using a solar cell module and specifically includes a solar cell module that performs power generation, a unit that converts electric power generated by the power generation, and a load that consumes electricity generated by electricity accumulating means or generated electricity. FIG. 5 shows a configuration conceptual diagram of the solar power generation system 400 of the embodiment. The solar power generation system of FIG. 5 includes a solar cell module 401 (300), a converter 402, a storage battery 403, and a load 404. Any one of the storage battery 403 and the load 404 may be omitted. The load 404 may be configured to be able to utilize the electric energy stored in the storage battery 403. The converter 402 is a device including a circuit or element, such as a DC-DC converter, a DC-AC converter, or an AC-AC converter, which performs power conversion being transformation, DC-AC conversion, or the like. A suitable configuration may be adopted for the converter 402 in accordance with a generated voltage and the configurations of the storage battery 403 and the load 404.

Solar cells included in the submodule 303, which is included in the solar cell module 300 and having received light, generate electricity and the electric energy thereof is converted by the converter 402 and stored in the storage battery 403 or consumed by the load 404. In the solar cell module 401, it is possible to provide a sunlight tracking drive device for constantly directing the solar cell module 401 to the sun, provide a light collector for collecting sunlight, and add a device for improving power generation efficiency, and the like.

It is preferable that the solar power generation system 400 be used for real estate such as residential, commercial facilities, and factories, and be used for movable items such as vehicles, aircraft and electronic equipment. An increase in power generation amount is expected by using the photoelectric conversion element having excellent conversion efficiency of the embodiment for the solar cell module 401.

Hereinafter, the embodiments will be described more specifically based on examples, but the embodiments is not limited to the following examples.

### Example 1

An ITO transparent conductive film is deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, an n-type Zn_{0.3}In_{1.4}S_{2.4} sulfide is deposited on the p-Cu₂O layer by sputtering, and an AZO transparent conductive film is deposited as a second electrode on the front surface side. By using sulfide of ZnₓIn₂₋₂ₓS₃₋₂ₓ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 2

An ITO transparent conductive film is deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using a sulfide of Cd_{y}Zn_{1-y}S for the n-type layer, oxidation of Cu₂O is prevented and the voltage and FF are improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 3

An ITO transparent conductive film is deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 4

An ITO transparent conductive film is deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of ZnₓIn₂₋₂ₓS₃₋₂ₓ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 5

An ITO transparent conductive film is deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 6

An ITO transparent conductive film is deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 7

First, an ITO transparent conductive film is deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of Zn_{0.3}In_{1.4}S_{2.4} for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 8

First, an ITO transparent conductive film is deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 9

First, an ITO transparent conductive film is deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 10

First, an ITO transparent conductive film is deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of Zn_{0.3}In_{1.4}S_{2.4} for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 11

First, an ITO transparent conductive film is deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 12

First, an ITO transparent conductive film is deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably 2 wt % or 3 wt %.

### Example 13

An ITO transparent conductive film and an ATO transparent conductive film are deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, an n-type Zn_{0.3}In_{1.4}S_{2.4} sulfide is deposited on the p-Cu₂O layer by sputtering, and an AZO transparent conductive film is deposited as a second electrode on the front surface side. By using sulfide of ZnₓIn₂₋₂ₓS₃₋₂ₓ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 14

An ITO transparent conductive film and an ATO transparent conductive film are deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using a sulfide of Cd_{y}Zn_{1-y}S for the n-type layer, oxidation of Cu₂O is prevented and the voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 15

An ITO transparent conductive film and an ATO transparent conductive film are deposited as a first electrode on a rear surface side on a soda-lime glass (alkali glass) substrate. A Cu₂O compound film is formed on a transparent first electrode by sputtering at 500° C. in an oxygen, nitrogen or argon gas atmosphere. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 16

An ITO transparent conductive film and an ATO transparent conductive film are deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of ZnₓIn₂₋₂ₓS₃₋₂ₓ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 17

An ITO transparent conductive film and an ATO transparent conductive film are deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 18

An ITO transparent conductive film and an ATO transparent conductive film are deposited as a first electrode on the rear surface side on an alkali-free glass substrate. A Cu₂O compound film is formed on a transparent first electrode by sputtering at 500° C. in an oxygen, nitrogen or argon gas atmosphere. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 19

First, an ITO transparent conductive film and an ATO transparent conductive film are deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of Zn_{0.3}In_{1.4}S_{2.4} for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 20

First, an ITO transparent conductive film and an ATO transparent conductive film are deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 21

First, an ITO transparent conductive film and an ATO transparent conductive film are deposited as a first electrode on the rear surface side on soda-lime glass (alkali glass). Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 22

First, an ITO transparent conductive film and an ATO transparent conductive film are deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type Zn_{0.3}In_{1.4}S_{2.4} is deposited on the p-Cu₂O layer by sputtering, and an AZO transparent conductive film is deposited as a second electrode on the front surface side. By using sulfide of Zn_{0.3}In_{1.4}S_{2.4} for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 23

First, an ITO transparent conductive film and an ATO transparent conductive film are deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n type Cd_{0.4}Zn_{0.6}S is deposited on the p-Cu₂O layer by sputtering, and an AZO transparent conductive film is deposited as a second electrode on the front surface side. By using sulfide of Cd_{0.4}Zn_{0.6}S for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

### Example 24

First, an ITO transparent conductive film and an ATO transparent conductive film are deposited as a first electrode on the rear surface side on a non-alkali glass substrate. Thereafter, Au or Mo dot electrodes are deposited in order to improve the conductivity while the opening is kept. A Cu₂O compound is deposited on the metal dots by sputtering at 500° C. in an atmosphere of oxygen, nitrogen and argon gas. Thereafter, at room temperature, a sulfide of n-type InGaS₃ is deposited on the p-Cu₂O layer by sputtering, and an AZO transparent conductive film is deposited as a second electrode on the front surface side. By using sulfide of InGaS₃ for the n-type layer, the oxidation of Cu₂O is prevented and a voltage FF is improved. Further, the obtained solar cell has an effect that, even in exposure to high temperature and high humidity for a long time (85° C., humidity 85%, 1000 hours), the oxidation of Cu₂O is suppressed and a decrease in the open voltage FF is prevented as compared with the case of depositing ZnO or Ga₂O₃ as the n-type layer. At the time of deposition of the second electrode on the front surface side, it is necessary to form a film at room temperature in order to suppress the oxidation of Cu₂O. However, by using AZO, a film with a low resistance can be obtained even at room temperature. For a target of AZO, a ratio of Al₂O₃ to ZnO is preferably between 2 wt % and 3 wt %.

In addition, each of the solar cells of Examples 1 to 24 is suitable as a top cell of a multijunction solar cell. Each of the solar cells of Examples 1 to 24 has a translucency and further has a band gap highly suitable as a top cell, and hence the solar cell has a small influence on power generation on the bottom cell side, and conversion and contribute to the improvement in efficiency as the multijunction solar cell.

Here, some elements are expressed only by element symbols thereof.

Clauses

### Clause 1

A solar cell comprising:

a first electrode;

a light absorption layer;

an n-type layer; and

a second electrode,

wherein

the light absorption layer exists between the first electrode and the n-type layer,

the n-type layer exists between the light absorption layer and the second electrode,

the light absorption layer contains Cu₂O, and

the n-type layer contains a sulfide.

### Clause 2

The solar cell according to clause 1, wherein the n-type layer is a layer containing one or more sulfides selected from a group consisting of a sulfide compound containing Zn and In, a sulfide compound containing Cd and Zn, and a sulfide compound containing In and Ga.

### Clause 3

The solar cell according to clause 1 or 2, wherein the n-type layer is a layer containing one or more sulfides selected from a group consisting of ZnₓIn₂₋₂ₓS₃₋₂ₓ, Cd_{y}Zn_{1-y}S, and In_{z}Ga_{1-z}S, and

the n-type layer satisfies that x is 0.0≤x≤0.6, y is 0.3≤y≤0.7, and z is 0.2≤z≤1.0.

### Clause 4

The solar cell according to any one of clauses 1 to 3, wherein

the n-type layer is a layer containing one or more sulfides selected from a group consisting of ZnₓIn₂₋₂ₓS₃₋₂ₓ, Cd_{y}Zn_{1-y}S, and In_{z}Ga_{1-z}S, and

the n-type layer satisfies that x is 0.0≤x≤0.3, y is 0.4≤y≤0.6, and z is 0.5≤z≤1.0.

### Clause 5

The solar cell according to any one of clauses 1 to 4, wherein a difference between a position of a conduction band minimum of the light absorption layer and a position of a conduction band minimum of the n-type layer is not smaller than −0.2 eV and not larger than 0.6 eV.

### Clause 6

A multijunction solar cell comprising:

the solar cell according to any one of clauses 1 to 5; and

a solar cell having a light absorption layer with a smaller band gap than a band gap of the light absorption layer of the solar cell according to any one of clauses 1 to 5.

### Clause 7

The multijunction solar cell according to clause 6, wherein the light absorption layer of the solar cell having the light absorption layer with a smaller band gap than the band gap of the light absorption layer of the solar cell according to any one of clauses 1 to 5 is a compound semiconductor or crystalline silicon.

### Clause 8

A solar cell module using the solar cell according to any one of clauses 1 to 5.

### Clause 9

A solar cell module using the solar cell according to any one of clauses 1 to 5 and a solar cell that has a light absorption layer with a smaller band gap than a band gap of the light absorption layer of the solar cell according to any one of clauses 1 to 5.

### Clause 10

A solar power generation system that performs solar power generation by using the solar cell module according to clause 8 or 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell comprising:
a substrate;
a first electrode on the substrate;
a light absorption layer;
an n-type layer; and
a second electrode,
wherein
the light absorption layer exists between the first electrode and the n-type layer,
the n-type layer exists between the light absorption layer and the second electrode,
the light absorption layer contains Cu₂O, and
the n-type layer contains a sulfide.

2. The solar cell according to claim 1, wherein the n-type layer is a layer containing one or more sulfides selected from a group consisting of a sulfide compound containing Zn and In, a sulfide compound containing Cd and Zn, and a sulfide compound containing In and Ga.

3. The solar cell according to claim 1, wherein
the n-type layer is a layer containing one or more sulfides selected from a group consisting of ZnₓIn₂₋₂ₓS₃₋₂ₓ, Cd_{y}Zn_{1-y}S, and In_{z}Ga_{1-z}S, and
the n-type layer satisfies that x is 0.0≤x≤0.6, y is 0.3≤y≤0.7, and z is 0.2≤z≤1.0.

4. The solar cell according to claim 1, wherein
the n-type layer is a layer containing one or more sulfides selected from a group consisting of ZnₓIn₂₋₂ₓS₃₋₂ₓ, Cd_{y}Zn_{1-y}S, and In_{z}Ga_{1-z}S, and
the n-type layer satisfies that x is 0.0≤x≤0.3, y is 0.4≤y≤0.6, and z is 0.5≤z≤1.0.

5. The solar cell according to claim 1, wherein a difference between a position of a conduction band minimum of the light absorption layer and a position of a conduction band minimum of the n-type layer is not smaller than −0.2 eV and not larger than 0.6 eV.

6. A multijunction solar cell comprising:
the solar cell according to claim 1; and
a solar cell having a light absorption layer with a smaller band gap than a band gap of the light absorption layer.

7. The multijunction solar cell according to claim 6, wherein the light absorption layer of the solar cell having the light absorption layer with a smaller band gap than the band gap of the light absorption layer of the solar cell is a compound semiconductor or crystalline silicon.

8. A solar cell module using the solar cell according to claim 1.

9. A solar cell module using the solar cell according to claim 1 and a solar cell that has a light absorption layer with a smaller band gap than a band gap of the light absorption layer of the solar cell according to claim 1.

10. A solar power generation system that performs solar power generation by using the solar cell module according to claim 8.

11. The solar cell according to claim 1, wherein the n-type layer is a layer containing a sulfide compound containing Cd and Zn.

12. The solar cell according to claim 1, wherein the n-type layer is a layer containing In_{z}Ga_{1-z}S, and the n-type layer satisfies that z is 0.2≤z≤1.0.

13. The solar cell according to claim 1, wherein a surface roughness of the n-type layer is not larger than 5 nm.

14. The solar cell according to claim 1, wherein the first electrode is in direct contact with the substrate and the light absorption layer.

15. The solar cell according to claim 14, wherein the first electrode is a layer existing between the substrate and the light absorption layer.
